(19) United States
(12) Patent Application Publication
(10) Pub. No.: US 2026/0361044 A1
(43) Pub. Date: Nov. 12, 2026

(54) FIBER-OPTIC PULSE PICKER AND STRETCHER

(71) Applicant: Coherent Scotland Limited, Glasgow (GB)

(72) Inventors: Ian MACGILLIVRAY, Glasgow (GB); Luke MAIDMENT, Glasgow (GB)

(73) Assignee: Coherent Scotland Limited, Glasgow (GB)

(21) Appl. No.: 19/125,555

(22) PCT Filed: Nov. 10, 2023
(86) PCT No.: PCT/GB2023/052951

§ 371 Date: Apr. 29, 2025

(30) Foreign Application Priority Data
Nov. 11, 2022 (GB) 2216828.0

(51) Int. Cl. H01S 3/106; H01S 3/23

(52) U.S. Cl. CPC H01S 3/1068; H01S 3/2325

(57) ABSTRACT

A fiber-optic system for laser pulse picking and stretching includes a circulator, a chirped fiber Bragg grating (cFBG), a retroreflector, and an acousto-optic switch. The acousto-optic switch is configured to (a) in a first operational state, transmit laser radiation between first and second switch ports and (b) in a second operational state, transmit laser radiation between the first switch port and a third switch port. The second switch port is coupled to the second of three circulator ports A, B, C. One of the first and third switch ports is coupled to the cFBG, and the other one of the first and third switch ports is coupled to the retroreflector, whereby the cFBG and the retroreflector form opposite ends of a linear multi-pass path passing through the acousto-optic switch. The circulator cooperates with the acousto-optic switch to integrate pulse picking and stretching in a solution that requires only a single three-port acousto-optic switch.

### CROSS-REFERENCE TO RELATED APPLICATIONS

This application is a U.S. national stage application under 35 U.S.C. § 371 of International Application No. PCT/GB2023/052951, filed Nov. 10, 2023, which claims the priority of GB Application No. 2216828.0, filed Nov. 11, 2022. The entire contents of each priority application is incorporated herein by reference.

### FIELD OF THE DISCLOSURE

The present invention relates to amplification of ultrashort laser pulses. The present invention relates in particular to systems for processing a train of ultrashort laser pulses to pick laser pulses for amplification and stretch the laser pulses prior to amplification.

### BACKGROUND OF THE DISCLOSURE

Chirped pulse amplification is a method for amplifying ultrashort laser pulses. Direct amplification of ultrashort pulses is often not feasible. Ultrashort laser pulses have durations of a few tens of picoseconds at most, for example between ten and a few hundred femtoseconds. The peak powers are correspondingly high, especially if amplified. Even if a laser amplifier is designed to handle the high peak powers, nonlinear effects are likely to cause an unacceptable degree of pulse distortion. Chirped pulse amplification overcomes these issues by lengthening the duration of the laser pulses prior to amplification, such that amplification is applied to laser pulses with reduced peak powers. The initially ultrashort pulse duration may be stretched to as much as nanoseconds. After amplification, the laser pulses are recompressed into the ultrashort regime.

Chirped pulse amplification utilizes the spectral bandwidth of ultrashort laser pulses to lengthen and shorten their duration. The stretcher of a chirped-pulse-amplification system chirps each laser pulse by imposing an optical path length that either increases or decreases with the wavelength of the laser radiation. This chromatic dispersion stretches the pulse. After amplification, the initial ultrashort pulse duration can be at least partly or approximately restored in a compressor that imposes the opposite chromatic dispersion. Either one of stretching and compression may be performed by, e.g., a pair of diffraction gratings, or a chirped Bragg grating. A chirped Bragg grating is generally simpler to align than a diffraction grating pair and can produce more stretching/compression in a more compact package.

In a chirped Bragg grating, the Bragg period either (a) increases with depth into the material, in which case shorter-wavelength light is reflected before longer-wavelength light, or (b) decreases with depth such that longer-wavelength light is reflected before shorter-wavelength light. A chirped Bragg grating may be implemented as a volume Bragg grating (VBG) in a bulk optic or as a chirped fiber Bragg grating (cFBG). A cFBG is an optical fiber with a chirped Bragg grating encoded in its core. A cFBG is often more practical than a volume Bragg grating, especially when the ultrafast laser pulses are generated in a fiber laser.

In a typical cFBG-based stretcher or compressor, a laser pulse to be stretched or compressed is directed into a first port of a three-port fiber-optic circulator. The fiber-optic circulator then directs the laser pulse to its second port to be launched into a cFBG connected thereto. Reflection of the laser pulse in the cFBG returns the laser pulse to the second port, whereafter the fiber-optic circulator emits the now stretched or compressed laser pulse from its third port.

The amount of amplification that can be applied to a stretched laser pulse is constrained by the peak power of the incident, stretched laser pulse. If the peak power becomes too high in the amplifier, nonlinear effects will distort the laser pulse and thereby adversely affect the ability to subsequently recompress the laser pulse. Therefore, the output pulse energy of a chirped-pulse-amplification system may ultimately be limited by how much the pulse can be stretched prior to amplification. In theory, arbitrary temporal stretching can be achieved using an arbitrarily long cFBG. However, cFBGs are not readily available in long lengths, e.g., beyond about 20 centimeters. This is in part because the challenges associated with encoding an accurate, and thus non-distorting, chirped grating increase with the length of the cFBG, thereby rendering the manufacture of longer cFBGs cost-prohibitive or impossible.

This length-limitation may be circumvented by subjecting the laser pulse to two or more passes through cFBGs. For example, as disclosed by Fermann et al. in European Patent EP2403076, two separate cFBGs may be connected to the second and third ports of a four-port fiber-optic circulator. In this arrangement, the laser pulse is first reflected in the cFBG connected to the second port and then reflected in the cFBG connected to the third port. In U.S. Pat. No. 7,444,049, Kim et al. take a different approach to the problem and achieve multiple passes in a single cFBG. The single cFBG is integrated in a multi-pass loop, and the number of passes through the multi-pass loop is controlled by an active switch. The multi-pass loop includes a circulator, and the cFBG is connected to the circulator such that the laser pulse is reflected once by the cFBG for each pass through the multi-pass loop. An active switch directs a laser pulse into the multi-pass loop and extracts the laser pulse from the multi-pass loop after completing the number of passes necessary to achieve the desired temporal stretching.

The amount of amplification that can be applied to a stretched laser pulse may also be limited by the time delay between pulses passing through the gain medium of the power amplifier. In many instances, the initial repetition rate of ultrashort laser pulses, as generated by the master oscillator, does not allow sufficient time for the population inversion in the power amplifier's gain medium to rebuild to a steady-state level between pulses. Therefore, many chirped pulse amplification systems incorporate a pulse picker that selects only a subset of the ultrashort laser pulses for amplification in the power amplifier. The pulse picker is, for example, an acousto-optic or electro-optic switch. In a typical scenario, the pulse picker reduces the pulse repetition rate by at least one or two orders of magnitude.

Zhang et al. discloses a multi-pass pulse stretcher that stretches laser pulses selected by a pulse picker (Chin. Opt. Lett. 11, 070606 (2013)). The architecture of this multi-pass stretcher is similar to that disclosed by Kim et al., namely with a cFBG connected to a circulator that is situated in a multi-pass loop. In the Zhang et al. system, the active switch controlling coupling of pulses into and out of the multi-pass loop is a 4-port acousto-optic modulator (AOM) with two input ports and two output ports. The multi-pass loop goes through the AOM via a first AOM input port and a first AOM output port. Laser pulses received at a second AOM input port are switched into the multi-pass loop and make a desired number of passes through the multi-pass loop before being switched out via a second AOM output port. The 4-port AOM is preceded by a pulse-picking AOM that reduces the repetition rate of laser pulses.

### SUMMARY OF THE DISCLOSURE

Disclosed herein is an integrated fiber-optic pulse picker and stretcher. The pulse picker and stretcher is suitable for implementation in chirped pulse amplification. Pulse stretching is achieved in a cFBG situated at one end of a linear multi-pass path passing through a fiber-optic AOM. The AOM serves as an active switch that switches laser pulses into and out of the linear multi-pass path. Since the multi-pass path is linear, stretched laser pulses are switched out of the multi-pass path via the same AOM port that first received the incoming laser pulses. This input/output port of the AOM is connected to a fiber-optic circulator that separates outgoing laser pulses from incoming laser pulses. As compared to loop-based multi-pass architectures with an AOM switch, such as that disclosed by Zhang et al., the linear multi-pass architecture of the present system renders one AOM port superfluous. This superfluous AOM port may be omitted entirely, such that the presently disclosed solution may be realized with a more affordable 3-port AOM. Furthermore, the present linear architecture allows the AOM to also function as a pulse-picker, thereby eliminating the need for a separate pulse picker. In one embodiment, “unpicked” laser pulses are discarded by directing these laser pulses toward the superfluous/omitted AOM port. Other embodiments implement polarization rotation that cooperates with polarization selectivity of the circulator to block unpicked laser pulses. In short, the present system integrates pulse picking and multi-pass cFBG-based pulse stretching in a fiber-optic solution that is simpler and more affordable than the prior-art pulse stretching schemes based on multiple passes in the same cFBG.

The present fiber-optic pulse picker and stretcher may include a gain fiber in the linear multi-pass path to achieve multi-pass amplification of the picked laser pulses. Such embodiments integrate three functions, namely pulse picking, pulse stretching, and pulse amplification, in a relatively simple and cost-effective solution. These embodiments may be implemented in chirped pulse amplification to provide preamplification in addition to pulse picking and stretching.

In one aspect, a fiber-optic system for laser pulse picking and stretching includes a circulator having first, second, and third circulator ports. The circulator is configured to (a) emit, from the second circulator port, laser radiation coupled into the first circulator port, and (b) emit, from the third circulator port, laser radiation coupled into the second circulator port. The system further includes a chirped fiber Bragg grating for stretching duration of a laser pulse reflected thereby, a retroreflector, and an acousto-optic switch having first, second, and third switch ports. The acousto-optic switch is configured to (a) in a first operational state, transmit laser radiation between the first and second switch ports and (b) in a second operational state, transmit laser radiation between the first and third switch ports. The second switch port is coupled to the second circulator port. One of the first and third switch ports is coupled to the chirped fiber Bragg grating, and the other one of the first and third switch ports is coupled to the retroreflector, whereby the chirped fiber Bragg grating and the retroreflector form opposite ends of a linear multi-pass path passing through the acousto-optic switch.

### BRIEF DESCRIPTION OF THE DRAWINGS

The accompanying drawings, which are incorporated in and constitute a part of the specification, schematically illustrate preferred embodiments of the present invention, and together with the general description given above and the detailed description of the preferred embodiments given below, serve to explain principles of the present invention.

FIG. 1 illustrates a fiber-optic pulse picking and stretching system with multi-pass pulse stretching in a cFBG situated at one end of a linear multi-pass path, according to an embodiment. Switching of laser pulses into and out of the linear multi-pass path is handled by an AOM. FIG. 1 further shows an exemplary use scenario wherein the pulse picking and stretching system is implemented in a laser apparatus with chirped pulse amplification.

FIG. 2 illustrates an implementation of the FIG. 1 system, wherein the two operational states of the AOM, used for switching, are on-and off-states configured such that (a) placing the AOM in its off-state allows transmission of a laser pulse along the multi-pass path while (b) coupling of a laser pulse into and out of the multi-pass path requires switching the AOM to its on-state.

FIG. 3 illustrates timing of laser pulses and AOM switching in one example of pulse picking and stretching by the FIG. 2 system, wherein picked laser pulses undergo two reflections in the cFBG.

FIG. 4 illustrates another implementation of the FIG. 1 system, wherein the two operational states of the AOM, used for switching, are on-and off-states. The FIG. 4 system is configured such that (a) placing the AOM in its off-state allows coupling of a laser pulse into and out of the multi-pass path and (b) transmission of a laser pulse along the multi-pass path through the AOM requires switching the AOM to its on-state. The FIG. 4 system utilizes a polarization-selective fiber-optic circulator together with polarization rotation by a fiber-optic Faraday rotator to reduce or eliminate leakage of unpicked laser pulses. Picked laser pulses undergo an even number of reflections in the cFBG.

FIG. 5 illustrates timing of laser pulses and AOM switching in one example of pulse picking and stretching by the FIG. 4 system, wherein picked laser pulses undergo two reflections in the cFBG.

FIG. 6 illustrates a modification of the FIG. 4 system that uses a Faraday mirror instead of an inline Faraday rotator, and wherein the cFBG is repositioned such that picked laser pulses undergo an odd number of reflections in the cFBG.

### DETAILED DESCRIPTION OF THE DISCLOSURE

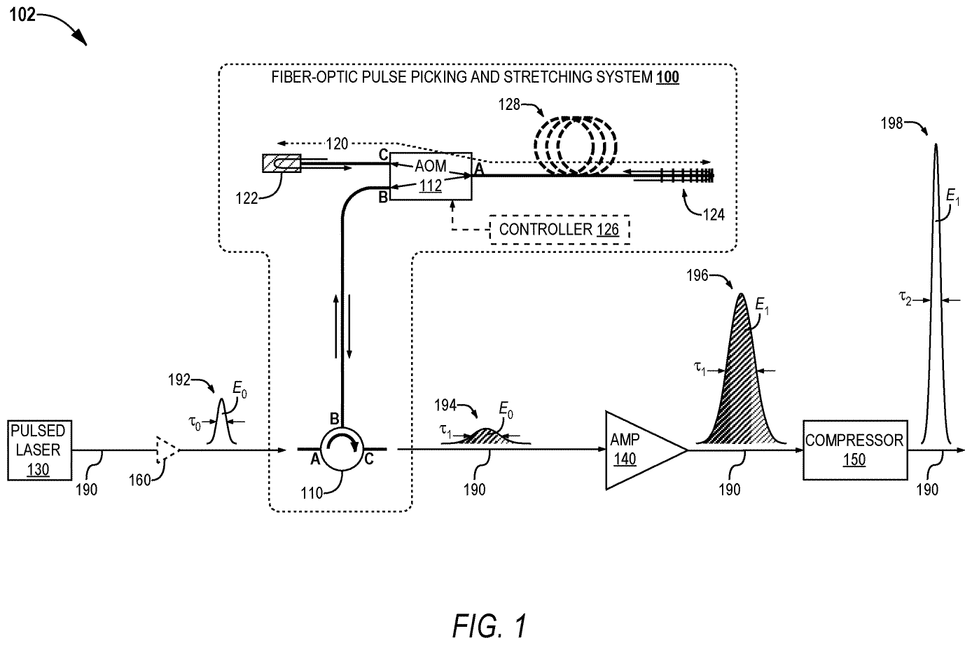

Referring now to the drawings, wherein like components are designated by like numerals, FIG. 1 illustrates one fiber-optic pulse picking and stretching system 100 with multi-pass pulse stretching in a cFBG situated at one end of a linear multi-pass path. Switching of laser pulses into and out of the linear multi-pass path is handled by an AOM. System 100 accepts ultrashort input laser pulses 192 and generates stretched laser pulses 194 from a subset of input pulses 192 picked from a pulse train. System 100 includes a fiber-optic circulator 110, a fiber-optic AOM 112 configured as a switch, a fiber-optic retroreflector 122, and a cFBG 124.

Circulator 110 has three ports denoted circulator port A, circulator port B, and circulator port C, respectively. Circulator 110 may be a 3-port circulator with no more than three ports. Laser radiation coupled into circulator port A is transmitted to circulator port B and emitted therefrom, and laser radiation coupled into circulator port B is transmitted to circulator port C and emitted therefrom. Circulator 110 may be polarization selective, in which case transmission of laser radiation from circulator port A to circulator port B and from circulator port B to circulator port C takes place only when the laser radiation is of a particular polarization. AOM 112 has three ports respectively denoted switch port A, switch port B, and switch port C. AOM 112 may be a 3-port AOM with no more than three ports. Switch port B is coupled to circulator port B. In the example depicted in FIG. 1, switch port A is coupled to cFBG 124, and switch port C is coupled to retroreflector 122. Alternatively, switch port A is coupled to retroreflector 122, and switch port C is coupled to cFBG 124. These couplings between circulator 110, AOM 112, retroreflector 122, and cFBG 124 may be fiber-couplings, each consisting of one or more optical fibers and, optionally, one or more fiber-optic components.

Retroreflector 122 may be implemented directly on or in an optical fiber. For example, retroreflector 122 may be a reflective coating on the end of an optical fiber or a reflective Bragg grating encoded in the optical fiber. Alternatively, retroreflector 122 may be a mirror mounted in a fiber-optic package.

When placed in a first operational state, AOM 112 transmits laser radiation between switch ports A and B. When placed in a second operational state, AOM 112 transmits laser radiation between switch ports A and C. System 100 may further include a controller 126 that switches AOM 112 between these two operational states. While AOM 112 is in its second operational state, AOM 112 completes a linear multi-pass path 120 between retroreflector 122 and cFBG 124. A laser pulse is coupled into and out of multi-pass path 120 by placing AOM 112 in its first operational state. The first and second operational states of AOM 112 may be on-and off-states, respectively, or vice versa. In the on-state, AOM 112 diffracts an incident laser pulse into a selected diffraction order, typically a first diffraction order. In the off-state, laser pulses pass through AOM 112 without being diffracted (or with negligible diffraction). In an ideal scenario, diffraction into the selected diffraction order takes place at 100% efficiency when AOM 112 is in an on-state. Deviations from this ideal scenario are discussed later in reference to specific embodiments of system 100.

In operation, system 100 receives input pulses 192 at circulator port A. Each input pulse 192 has a duration τ₀ and an energy E₀. Circulator 110 transmits input pulses 192 to circulator port B, wherefrom input pulses 192 propagate to switch port B. If AOM 112 is in its first operational state when an input pulse 192 reaches switch port B from circulator 110, this input pulse 192 proceeds to switch port A to be coupled into multi-pass path 120. After coupling of this input pulse 192 into multi-pass path 120, AOM 112 may be switched to its second operational state to allow input pulse 192 to make a desired number of reciprocal passes along multi-pass path 120. Each pass involves a reflection in cFBG 124 that stretches the duration of this input pulse 192. In this manner, the selected input pulse 192 is picked from the pulse train and subjected to stretching. After the desired number of reflections in cFBG 124, AOM 112 is switched back to its first operational state to couple this picked laser pulse, now in the form of stretched pulse 194, to switch port B. Stretched pulse 194 has a duration τ₁ that exceeds duration τ₀, for example by several orders of magnitude. From switch port B, stretched pulse 194 proceeds to circulator port B to be emitted from circulator port C.

Certain embodiments of system 100 further include a gain fiber 128 in multi-pass path 120. Gain fiber 128 amplifies input pulses 192 passing therethrough. Gain fiber 128 may be positioned anywhere along multi-pass path 120 between retroreflector 122 and cFBG 124. Each picked input pulse 192 will make at least two passes through gain fiber 128 and thus be amplified at least twice.

FIG. 1 depicts an ideal, lossless scenario, wherein the energy of stretched pulse 194 is the same as the energy of input pulse 192, indicated in FIG. 1 as E₀. In the absence of gain fiber 128, practical implementations of system 100 are likely to impose losses, such that the energy of stretched pulse 194 is less than E₀. As compared to the peak power of input pulse 192, the peak power of stretched pulse 194 is reduced by approximately a factor of τ₁/τ₀ in the lossless scenario, and more if losses are incurred.

FIG. 1 illustrates one exemplary use scenario for system 100, wherein system 100 is implemented in a laser apparatus 102 with chirped pulse amplification. In addition to system 100, apparatus 102 includes a pulsed laser 130, an amplifier 140, and a compressor 150. Laser 130 generates a laser beam 190 of input pulses 192. Apparatus 102 applies chirped pulse amplification to a picked subset of input pulses 192 by processing of laser beam 190 in system 100, amplifier 140, and compressor 150.

After pulse picking and stretching in system 100, amplifier 140 amplifies each stretched pulse 194 to generate a respective amplified, stretched laser pulse 196. The duration of amplified, stretched pulse 196 is typically approximately τ₁ but its pulse energy is increased to a value E₁ that is significantly higher than E₀.

Compressor 150 unchirps each stretched, amplified pulse 196 to shorten its duration and thereby generate a respective amplified, ultrashort laser pulse 198. Compressor 150 shortens the pulse duration by imposing a chromatic dispersion with the opposite sign of the chromatic dispersion imposed by system 100. In an ideal scenario, each amplified, ultrashort pulse 198 is characterized by the original pulse duration τ₀ of input pulses 192. In many practical scenarios, however, the duration τ₂ of each amplified, ultrashort pulse 198 exceeds τ₀ by at least a small amount. Such a discrepancy is often caused by (a) temporal or spectral pulse distortion in one or both of system 100 and amplifier 140 and/or (b) a mismatch between the respective chromatic dispersions imposed by compressor 150 and system 100. For a nearly lossless embodiment of compressor 150, the energy of amplified, ultrashort pulse 198 is close to E₁.

Compressor 150 may compress amplified, stretched pulses 196 in one or more cFBGs configured to impose a chromatic dispersion of the opposite sign compared to the chromatic dispersion imposed by cFBG 124. Alternatively, compressor 150 may utilize a volume Bragg grating or one or more diffraction gratings to unchirp amplified, stretched pulse 196. Diffraction gratings may be better suited than cFBGs to handle the relatively high peak powers developing as the duration of amplified, stretched pulse 196 is being shortened.

The architecture of apparatus 102 may be applied in a range of scenarios, for example based on different types of lasers 130 and, accordingly, different characteristics of input pulses 192. Laser 130 is, for example, a fiber laser, a diode laser, or a diode-pumped solid-state laser. Pulse duration τ₀ may be less than 10 picoseconds (ps), for example in the range between 10 femtoseconds (fs) and 1 ps. The wavelength of input pulses 192 may be in the range between 900 and 2200 nanometers (nm) or in the range between 1000 and 1100 nm. Laser 130 may generate input pulses 192 with pulse energy E₀ in the range between 0.1 picojoules and 5 nanojoules (nJ) and at a repetition rate as high as 200 megahertz (MHz), for example in the range between 5 MHz and 200 MHz. System 100 reduces the pulse repetition rate to a frequency more suitable for amplifier 140, for example between 0.5 and 10 MHz. In embodiments of apparatus 102 where system 100 includes gain fiber 128, system 100 preamplifies the laser pulses prior to amplification by amplifier 140. Alternatively, or in combination with preamplification provided by system 100, apparatus 102 may include one or more separate preamplifiers. In the embodiment depicted in FIG. 1, a preamplifier 160 amplifies input pulses 192 prior to processing by system 100. In another embodiment, not depicted in FIG. 1, a preamplifier is positioned between system 100 and amplifier 140. Whether performed by gain fiber 128 in system 100 and/or another preamplifier, preamplification may amplify the pulse energy to, e.g., between 0.1 and 500 nJ prior to amplifier 140.

In most practical AOMs, the only way to achieve 100% transmission into a single output order is to place the AOM in its off-state where all transmitted energy is in the non-diffracted zeroth order. In an on-state of the AOM, the energy diffracted into, e.g., the first diffraction order is usually limited to between about 80% and about 95% of the incident energy, while the majority of the rest of the incident energy remains in the non-diffracted zeroth order. This practical limitation leads to imperfect switching by AOM 112 in system 100. Imperfect switching has implications for the performance of system 100. While it is most often advantageous to have one of the two operational states of AOM 112 be the off-state, some scenarios benefit from the first operational state being the off-state and other scenarios benefit from the second operational state being the off-state.

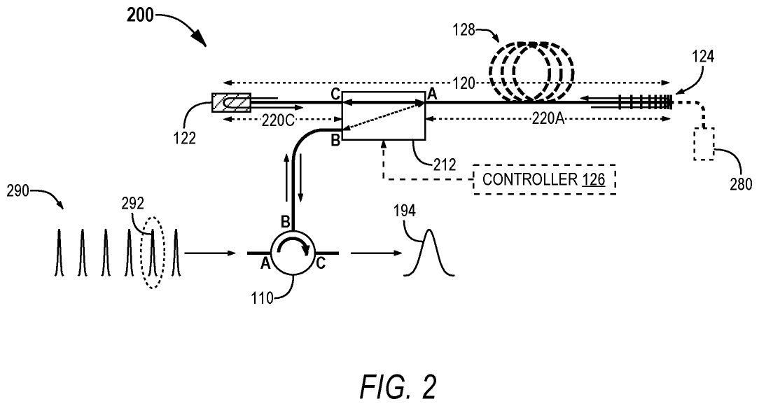

FIG. 2 illustrates a fiber-optic pulse picking and stretching system 200. System 200 is an embodiment of system 100 wherein AOM 112 is implemented as an AOM 212. The two operational states of AOM 212 in system 200 are on-and off-states configured such that (a) placing AOM 212 in its off-state allows transmission of a laser pulse along multi-pass path 120 while (b) coupling of a laser pulse into and out of multi-pass path 120 requires switching AOM 212 to its on-state. cFBG 124 is at the end of a segment 220A of multi-pass path 120 extending away from switch port A. Retroreflector 122 is at the end of another segment 220C of multi-pass path 120 extending away from switch port C.

In operation, system 200 receives a train 290 of input pulses at circulator port A. Pulse train 290 propagates to switch port B of AOM 212. AOM 212 is initially in its off-state. AOM 212 is switched to its on-state only just before the arrival of a to-be-picked input pulse 292, so as to allow coupling of input pulse 292 into multi-pass path 120 via switch port A. The preceding input pulses that arrived while AOM 212 was in its off-state were blocked by AOM 212 and transmitted to neither one of switch ports A and C. While the picked input pulse 292 propagates in segment 220A, AOM 212 is switched back to its off-state to allow input pulse 292 to propagate on multi-pass path 120 through AOM 212 to retroreflector 122. Preferably, this switch happens before a subsequent input pulse arrives at switch port B. The picked input pulse 292 propagates back and forth on multi-pass path 120 between cFBG 124 and retroreflector 122 until AOM 212 is once again switched to its on-state, while input pulse 292 is in segment 220A, so as to couple input pulse 292 out of multi-pass path 120 and back to circulator 110 in the form of stretched pulse 194.

It is also possible to operate AOM 212 such that input pulse 292 is reflected only once in cFBG 124 without ever entering segment 220C of multi-pass path 120. However, at least as far as pulse stretching is concerned, that particular switching scheme fails to benefit from the multi-pass capability of system 200.

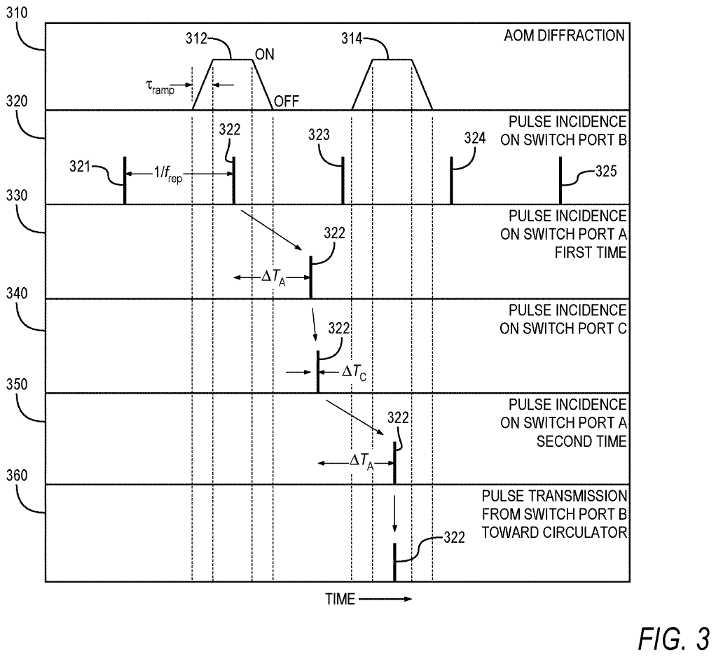

FIG. 3 illustrates timing of laser pulses and AOM switching in one example of pulse picking (and stretching) by system 200 wherein picked input pulses undergo two reflections in cFBG 124. FIG. 3 contains timing diagrams 310, 320, 330, 340, 350, and 360, all sharing the same temporal axis. In the FIG. 3 example, system 200 receives a laser pulse train of five input pulses 321, 322, 323, 324, and 325. In this example, only pulse 322 is to be picked by system 200. The pulse train is characterized by a repetition rate fᵣₑₚ such that the input pulses are spaced apart by a time 1/fᵣₑₚ. Diagram 310 plots the diffraction efficiency of AOM 212. AOM 212 is turned on twice to couple pulse 322 into and out of multi-pass path 120 (see in-coupling AOM gate 312 and out-coupling AOM gate 314). Diagrams 320, 330, 340, 350, and 360 show arrival of laser pulses at different stages in the pulse picking and stretching process. Diagram 320 plots laser pulses incident on switch port B from circulator port B. Diagram 330 plots laser pulses incident on switch port A after a first reflection in cFBG 124. Diagram 340 plots laser pulses incident on switch port C after subsequent reflection by retroreflector 122. Diagram 350 plots laser pulses incident on switch port A after a subsequent second reflection in cFBG 124. Finally, diagram 360 plots laser pulses transmitted from switch port B toward circulator 110.

Initially, AOM 212 is in its off-state and remains in its off-state until after pulse 321 has reached switch port B from circulator 110. With AOM 212 in its off-state, the full energy of pulse 321 is blocked by AOM 212. AOM 212 is switched to its on-state just before to-be-picked pulse 322 arrives at switch port B from circulator 110 (see in-coupling AOM gate 312). AOM 212 remains in the on-state until after pulse 322 is transmitted to switch port A and thus coupled into segment 220A of multi-pass path 120. AOM 212 is switched back to its off-state before pulse 322 returns to switch port A after the first reflection in cFBG 124, such that pulse 322 is transmitted to switch port C to propagate in segment 220C toward retroreflector 122. Since this transmission takes place in the off-state of AOM 212, there is no partial transmission of laser energy to switch port B.

The transitions between off-and on-states are not instantaneous but are instead associated with a non-zero ramp time τᵣₐₘₚ. The length of segment 220A must be sufficient that the total propagation time ATA of pulse 322 from AOM 212 to cFBG 124 and back to AOM 212 exceeds Tramp. Fiber-optics AOMs commonly have ramp times in the range between 5 and 50 nanoseconds (ns). Thus, the length of segment 220A may be in the range between approximately 1 and 10 meters (m). While not required for proper picking and “unpicking” of input pulses, it is simplest if pulse 322 returns to switch port A, for the first time, before the next pulse 323 arrives at switch port B from circulator 110, as depicted in FIG. 3. In this scenario, the out-and-back propagation time in segment 220A must be less than 1/fᵣₑₚ. This limitation is compatible with repetition rates fᵣₑₚ up to about 100 MHz while also maintaining an out-and-back propagation time in segment 220A that exceeds Tramp for a typical AOM.

After propagating from AOM 212 to retroreflector 122 and back to AOM 212, pulse 322 arrives at switch port C. At this time, AOM 212 is in its off-state such that pulse 322 is transmitted to segment 220A to undergo a second reflection in cFBG 124. Since no AOM switching is required during the propagation of pulse 322 in segment 220C, the out-and-back propagation time ΔT_{C} of pulse 322 from AOM 212 to retroreflector 122 and back to AOM 212, and thus the length of segment 220C, may be made arbitrarily short. In fact, a short propagation length and thus short propagation time ΔT_{C} in segment 220C may make it easier to couple picked laser pulses into and out of multi-pass path 120 without also inadvertently coupling not-to-be-picked laser pulses into multi-pass path 120.

While pulse 322 makes its second out-and-back trip in segment 220A, AOM 212 is switched to its on-state in order to couple the now twice-stretched pulse 322 out of multi-pass path 120 and transmit pulse 322 to circulator 110 (see out-coupling AOM gate 314). After this out-coupling of pulse 322, AOM 212 is switched back to its off-state. In the scenario depicted in FIG. 3, propagation lengths in segments 220A and 220C are coordinated with repetition rate fᵣₑₚ such that no other input pulses arrive at switch port B from circulator 110 while AOM 212 is in its on-state. In an alternative scenario, out-coupling of one picked laser pulse coincides with in-coupling of a next picked laser pulse.

Referring again to FIG. 2, system 200 may include gain fiber 128 in segment 220A. The length of gain fiber 128 may be in the range between 100 millimeters and several meters in order to provide sufficient amplification. The positioning of gain fiber 128 in segment 220A is convenient in scenarios where a substantial length of optical fiber (e.g., several meters) are required in segment 220A in order to fully switch the state of AOM 212 during propagation of the picked laser pulse in segment 220A, as discussed above in reference to FIG. 3. System 200 may also include a pump laser 280, such as a laser diode, that is fiber coupled to segment 220A. In the example depicted in FIG. 2, pump laser radiation from pump laser 280 is coupled into segment 220A via cFBG 124.

In a modification of system 200, the positions of retroreflector 122 and cFBG 124 may be interchanged. In the depicted configuration, input pulse 292 undergoes an even number of reflections in cFBG 124. With the positions of retroreflector 122 and cFBG 124 interchanged, input pulse 292 undergoes any desired integer number of reflections in cFBG 124.

Optional gain fiber 128 may be moved to segment 220C, although this may lead to a substantial overall lengthening of multi-pass path 120 as well as add complexity to the AOM switching scheme. When gain fiber 128 is in the segment of multi-pass path 120 terminating in retroreflector 122, as opposed to cFBG 124, pump laser radiation from pump laser 280 may be coupled into this segment of multi-pass path 120 via a wavelength division multiplexer or via a dichroic implementation of retroreflector 122.

Regardless of the number of reflections in cFBG 124, a picked input pulse 292 is transmitted twice by AOM 212 in its on-state, first when input pulse 292 is coupled into multi-pass path 120 and later when input pulse 292 is coupled out of multi-pass path 120 in the form of stretched pulse 194. With practical implementations of AOM 212, each of these two passes through AOM 212 introduces a loss, for example between 5% and 15% per pass. Gain fiber 128 may compensate for this loss. In fact, this loss may be negligible compared to the amplification provided by gain fiber 128. However, in embodiments of system 200 that include gain fiber 128, the imperfect switching of practical implementations of AOM 212 may lead to build-up of amplified spontaneous emission (ASE) radiation along multi-pass path 120. When AOM 212 is in its off-state, retroreflector 122 and cFBG 124 form a linear resonator. Due to imperfect switching, this resonator is maintained even when AOM 212 is in its on-state (albeit with a substantial loss imparted by AOM 212), and ASE radiation generated in gain fiber 128 may therefore build up to a level that reduces the achievable amplification of picked input pulse 192 in gain fiber 128. This issue may be mitigated by reversing the switching scheme of the AOM, as discussed in the following.

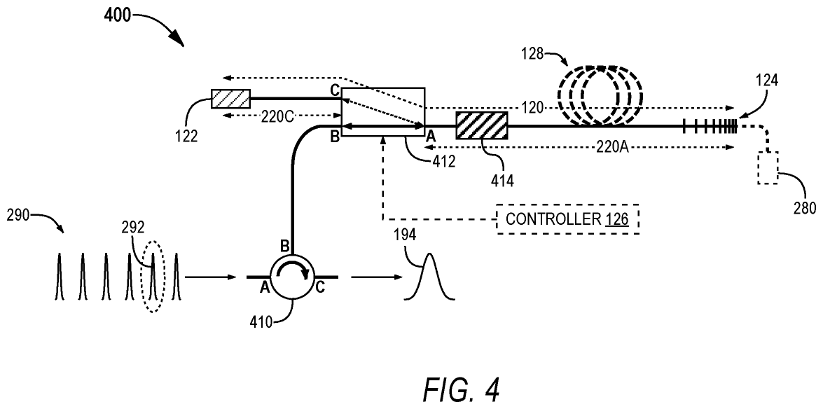

FIG. 4 illustrates a fiber-optic pulse picking and stretching system 400. System 400 is another embodiment of system 100, similar to system 200, but implementing AOM 112 as an AOM 412 that has the opposite switching logic from AOM 212. With the switching logic of AOM 412, a resonator between retroreflector 122 and cFBG 124 is formed only when AOM 412 is in its on state. The configuration of system 400 may therefore be preferable over that of system 200 when gain fiber 128 is included. However, unpicked laser pulses are at least partly transmitted by AOM 412. Leakage of unpicked laser pulses is undesirable in some situations. Consider, for example, a scenario where system 400 is implemented in apparatus 102. In this scenario, the energy of unpicked laser pulses could prevent amplifier 140 from providing the desired gain in amplification of picked laser pulses. To prevent such issues, system 400 utilizes polarization rotation and selectivity to block unpicked laser pulses.

In its off-state, AOM 412 transmits laser radiation between switch ports A and B. In its on-state, AOM 412 diffracts laser radiation to facilitate transmission between switch ports A and C. Placing AOM 412 in its off-state allows coupling of a laser pulse into and out of multi-pass path 120. Transmission of a laser pulse along multi-pass path 120, from segment 220A to segment 220C and vice versa, requires switching AOM 412 to its on-state. In one operating scheme, AOM 412 is in its off-state most of the time, such that a resonator between retroreflector 122 and cFBG 124 is formed only during the relatively short time periods where AOM 412 is placed in its on-state to keep a picked laser pulse in multi-pass path 120. While AOM 412 is in its off-state, input pulses incident on switch port B are transmitted to switch port A and make a single out-and-back trip in segment 220A of multi-pass path 120 to undergo a single reflection in cFBG 124 before returning to circulator 410.

System 400 includes a fiber-optic Faraday rotator 414 in segment 220A and implements circulator 110 as a polarization selective circulator 410. Circulator 410 transmits laser radiation of a particular polarization, for example linearly polarized along a particular polarization direction. Circulator 410 blocks laser radiation of the orthogonal polarization. Preferably, pulse train 290 is incident on circulator port A with the polarization transmitted by circulator 410. Regardless, circulator 410 functions as a polarizer such that the input laser pulses are polarized when emitted from circulator port B in the direction toward AOM 412. Faraday rotator 414 is configured to exert a 45-degree polarization rotation on laser radiation passing therethrough. An out-and-back trip in segment 220A therefore results in a 90-degree polarization rotation, such that input pulses making only a single out-and-back trip in segment 220A return to circulator port B with the orthogonal polarization that is blocked by circulator 410.

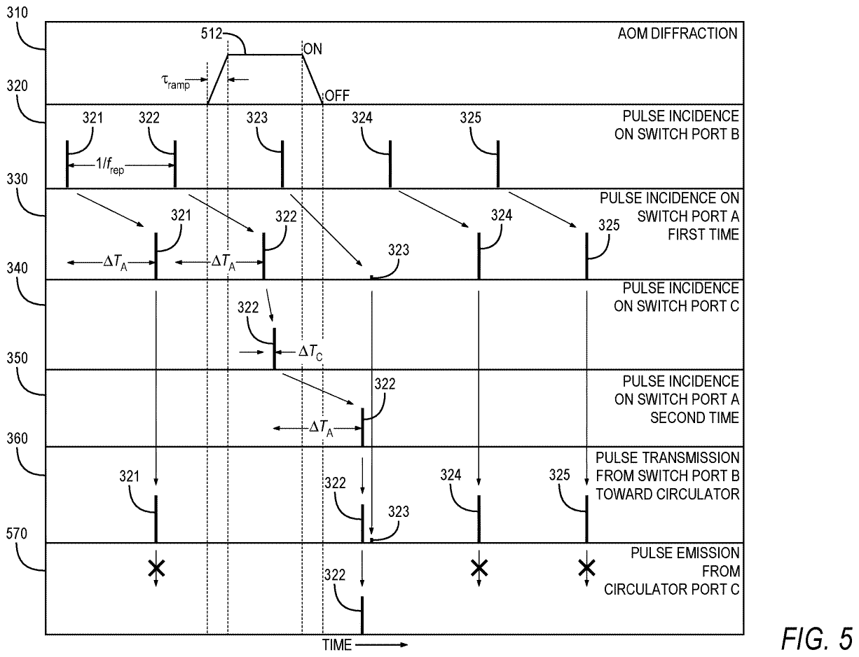

FIG. 5 illustrates timing of laser pulses and AOM switching in one example of pulse picking (and stretching) by system 400 wherein picked input pulses undergo two reflections in cFBG 124. FIG. 5 contains timing diagrams 310, 320, 330, 340, 350, and 360 similar to those of FIG. 3, but for the switching configuration of AOM 412. In addition, FIG. 5 contains a timing diagram 570 indicating pulse emission from circulator port C on the same temporal scale. As in the FIG. 3 example for system 200, system 400 here receives the pulse train of pulses 321, 322, 323, 324, and 325, from which only pulse 322 is to be picked by system 400. For simplicity, the FIG. 5 diagrams assume that gain fiber 128 is omitted and that there is no gain in system 400.

First, consider the propagation of to-be-picked pulse 322 through system 400. AOM 412 is initially in its off-state and remains in its off-state until after pulse 322 arrives at switch port B from circulator 410 and is coupled into segment 220A of multi-pass path 120. AOM 412 is switched to its on-state (see AOM gate 512) while pulse 322 propagates in segment 220A and before pulse 322 returns to switch port A after a first reflection in cFBG 124. AOM 412 thereby transmits pulse 322 to segment 220C. AOM 412 is still in its on-state when pulse 322 returns to switch port C after reflection by retroreflector 122. While pulse 322 propagates in segment 220A to undergo a second reflection in cFBG 124, AOM 412 is switched back to its off-state. Thus, when arriving at switch port A after the second reflection in cFBG 124, the twice-stretched pulse 322 is coupled out of multi-pass path 120 and returned to circulator 410. Twice-stretched pulse 322 passes through Faraday rotator 414 four times to undergo a total polarization rotation of 180 degrees. Thus, twice-stretched pulse 322 is transmitted from circulator port B to circulator port C and emitted therefrom.

Unpicked laser pulses are also at least partly returned to circulator 410. Each of pulses 321, 324, and 325 makes one out-and-back pass in segment 220A while AOM 412 is in its off-state. Pulses 321, 324, and 325 are therefore returned to circulator 410 after being stretched once in cFBG 124. Moreover, in practical implementations, pulses 321, 324, and 325 have greater energy than picked pulse 322 when returning to circulator 410, because only picked pulse 322 is subject to diffraction loss in AOM 412. Pulse 323 arrives at switch port B from circulator 410 while AOM 412 is in its on-state (for the purpose of transmitting picked pulse 322 to and from segment 220C). Due to the sub-unity diffraction efficiency of practical implementations of AOM 412, a fraction of pulse 323 is coupled into segment 220A and reflected once by cFBG 124 before returning to AOM 412. At that time, AOM 412 is in its off-state and transmits the attenuated and once-stretched pulse 322 to circulator port B. However, each of pulses 321, 323, 324, and 325 passes through Faraday rotator 414 twice to undergo a total polarization rotation of 90 degrees. Circulator 410 therefore blocks these unpicked laser pulses.

The FIG. 5 example is readily extendable to more than two reflections in cFBG 124 for picked pulses. However, in order for picked laser pulses to be transmitted from circulator port B to circulator port C, the number of passes of the picked laser pulses through Faraday rotator 414 must be an integer multiple of four, corresponding to an even number of reflections in cFBG 124.

Optical fibers in system 400, used to couple AOM 412 to circulator 410, retroreflector 122, and cFBG 124, may be polarization maintaining in order to minimize inadvertent polarization rotation. Yet, in practical implementations, the polarization selectivity of circulator 410 is not perfect, and some amount of polarization errors are likely introduced during propagation in system 400. As a result, some leakage of unpicked laser pulses may persist. Yet, the polarization-based suppression of leakage in system 400 has been found to very effective, especially in embodiments of system 400 that include gain fiber 128. Since picked laser pulses make more passes through gain fiber 128, gain fiber 128 amplifies picked laser pulses more than unpicked laser pulses. Certain practical implementations of system 400 including gain fiber 128 have been demonstrated to reduce the leaked energy of an unpicked laser pulse to a level that is between 23 and 26 dB less than the energy of a picked laser pulse that undergoes two reflections in cFBG 124 and makes two four passes through gain fiber 128.

In scenarios where gain fiber 128 has a relatively high gain and/or picked laser pulses make a relatively large number of passes through gain fiber 128, the stronger amplification of picked laser pulses may in itself render the energy of unpicked laser pulses insignificant. In such scenarios, the polarization-based suppression of unpicked laser pulses performed by Faraday rotator 414 in cooperation with polarization selective circulator 410 may be unnecessary, in which case Faraday rotator 414 may be omitted and circulator 410 may be replaced by a polarization-insensitive circulator.

Although not shown in FIG. 4, system 400 may implement gain fiber 128 in segment 220C instead of in segment 220A. This would entirely prevent amplification of unpicked laser pulses making only a single out-and-back trip in segment 220A, but the number of passes through gain fiber 128 for picked laser pulses would also be reduced by two. Thus, the ratio of energy of a picked pulse to energy of an unpicked laser pulse is largely insensitive to whether gain fiber 128 is implemented in segment 220A or 220C. However, positioning of gain fiber 128 in segment 220A may be preferred for the reasons discussed above within the context of system 200.

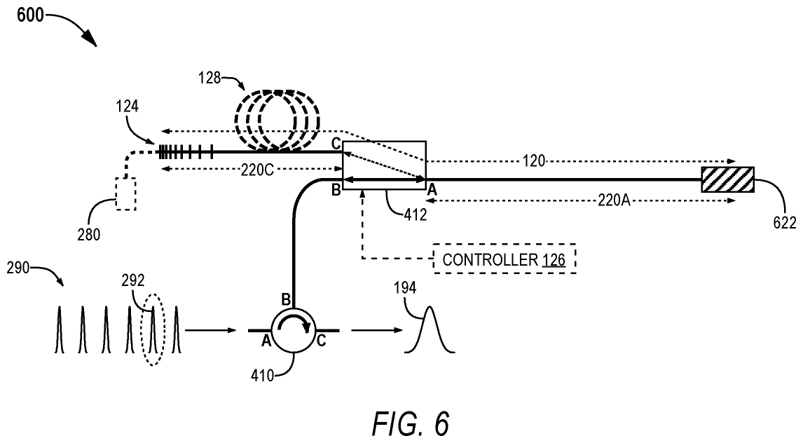

FIG. 6 illustrates another fiber-optic pulse picking and stretching system 600 that utilizes polarization rotation and selectivity to reduce or eliminate leakage of unpicked laser pulses. System 600 is a modification of system 400, wherein cFBG 124 is moved to the end of segment 220C, and retroreflector 122 is implemented at the end of segment 220A in the form of a Faraday mirror 622. Faraday 622 is equivalent to an embodiment of retroreflector 122 that integrates Faraday rotator 414. Reflection of laser radiation in Faraday mirror imposes a 90-degree polarization rotation. In system 600, picked laser pulses undergo an odd number of reflections in cFBG 124 in system 400. In contrast, system 400 is configured for an even number of reflections of picked laser pulses in cFBG 124.

System 600 may include gain fiber 128. In the example depicted in FIG. 6, gain fiber 128 is positioned in segment 220C such that pump laser radiation from pump laser 280 may be coupled into gain fiber 128 via cFBG 124. Gain fiber 128 may instead be positioned in segment 220A, which may provide for more optimal propagation lengths in segments 220A and 220C in some scenarios, as discussed above in reference to system 200.

In each of systems 100, 200, and 400, retroreflector 122 may be a second cFBG. Such inclusion of a second cFBG provides a greater amount of stretching per pass along multi-pass path 120, whereby a desired amount of stretching may be achieved with fewer passes than in embodiments having only a single cFBG. In practical implementations, each pass along multi-pass path is associated with loss. Especially in embodiments that do not include gain fiber 128, it may therefore be desirable to minimize the number of passes along multi-pass path 120. On the other hand, cFBG 124 may be the most expensive single component in the system, and the addition of a second cFBG likely represents a substantial increase in total cost.

The present invention is described above in terms of a preferred embodiment and other embodiments. The invention is not limited, however, to the embodiments described and depicted herein. Rather, the invention is limited only by the claims appended hereto.

What is claimed is:

1. A fiber-optic system for laser pulse picking and stretching, comprising:
a circulator having first, second, and third circulator ports and configured to (a) emit, from the second circulator port, laser radiation coupled into the first circulator port, and (b) emit, from the third circulator port, laser radiation coupled into the second circulator port;
a chirped fiber Bragg grating for stretching duration of a laser pulse reflected thereby;
a retroreflector; and
an acousto-optic switch having first, second, and third switch ports and configured to (a) in a first operational state, transmit laser radiation between the first and second switch ports and (b) in a second operational state, transmit laser radiation between the first and third switch ports, the second switch port being coupled to the second circulator port, one of the first and third switch ports being coupled to the chirped fiber Bragg grating and the other one of the first and third switch ports being coupled to the retroreflector, whereby the chirped fiber Bragg grating and the retroreflector form opposite ends of a linear multi-pass path passing through the acousto-optic switch.

2. The fiber-optic system of claim 1, further comprising a gain fiber in the multi-pass path.

3. The fiber-optic system of claim 2, wherein the first operational state of the acousto-optic switch is an off-state, and the second operational state of the acousto-optic switch is an on-state that diffracts laser radiation to achieve transmission between the first and third switch ports.

4. The fiber-optic system of claim 2, further comprising a pump laser for energizing the gain fiber, the gain fiber being in a segment of the multi-pass path that is between the chirped fiber Bragg grating and the acousto-optic switch.

5. The fiber-optic system of claim 2, wherein the gain fiber is in a segment of the multi-pass path that is between the retroreflector and the acousto-optic switch.

6. The fiber-optic system of claim 1, wherein the first operational state of the acousto-optic switch is an on-state that diffracts laser radiation to achieve transmission between the first and second switch ports, and the second operational state of the acousto-optic switch is an off-state.

7. The fiber-optic system of claim 1, wherein the circulator is polarization selective, and the system further includes a Faraday rotator in a first segment of the multi-pass path that starts at the first switch port and extends away from the acousto-optic switch, the Faraday rotator being arranged such that two passes of linearly polarized laser radiation through the Faraday rotator results in a ninety-degree polarization rotation.

8. The fiber-optic system of claim 7, wherein the first segment of the multi-pass path ends in the chirped fiber Bragg grating.

9. The fiber-optic system of claim 8, further comprising a gain fiber in the first segment of the multi-pass path.

10. The fiber-optic system of claim 9, the first operational state of the acousto-optic switch is an off-state, and the second operational state of the acousto-optic switch is an on-state that diffracts laser radiation to achieve transmission between the first and third switch ports.

11. The fiber-optic system of claim 7, wherein the first segment of the multi-pass path ends at the retroreflector, and the Faraday rotator is integrated with the retroreflector.

12. The fiber-optic system of claim 11, further comprising a gain fiber in a second segment of the multi-pass path spanning between the third switch port and the chirped fiber Bragg grating.

13. The fiber-optic system of claim 7, wherein the acousto-optic switch is coupled to each of the circulator, the chirped fiber Bragg grating, and the retroreflector via one or more polarization-maintaining optical fibers.

14. The fiber-optic system of claim 7, wherein the circulator is configured such that (a) laser radiation emitted from the second circulator port is linearly polarized along a first polarization direction, and (b) only laser radiation incident on the second circulator port with linear polarization along the first polarization direction is transmitted to the third circulator port.

15. The fiber-optic system of claim 1, wherein:
the acousto-optic switch is characterized by a ramp time between the first and second operational states,
a first segment of the multi-pass path starts at the first switch port and extends a first distance away from the acousto-optic switch to a corresponding end of the multi-pass path, the first distance imposing a transit time of laser pulses from the first switch port via the corresponding end of the multi-pass path back to the first switch port, the transit time exceeding the ramp time.

16. The fiber-optic system of claim 15, further comprising a gain fiber in the first segment of the multi-pass path.

17. A pulsed laser apparatus, comprising:
the system of claim 1;
a pulsed laser coupled to the first circulator port and configured to generate a train of laser pulses; and
a controller configured to operate the acousto-optic switch to pick a subset of the laser pulses, the picked laser pulses being subjected to more passes in the chirped fiber Bragg grating than unpicked laser pulses.

18. The apparatus of claim 17, further comprising a laser amplifier arranged to receive the picked laser pulses from the third circulator port and configured to amplify the picked laser pulses.

19. The apparatus of claim 18, further comprising a compressor configured to compress the duration of the picked laser pulses after amplification by the laser amplifier.

20. The apparatus of claim 17, further comprising a gain fiber in the multi-pass path.
